(19) United States
(12) Patent Application Publication
(10) Pub. No.: US 2015/0069413 A1
(43) Pub. Date: Mar. 12, 2015

(54) SEMICONDUCTOR DEVICE

(71) Applicant: Kabushiki Kaisha Toshiba, Tokyo (JP)

(72) Inventor: Kohei Morizuka, Hyogo-ken (JP)

(73) Assignee: KABUSHIKI KAISHA TOSHIBA, Tokyo (JP)

(21) Appl. No.: 14/201,695

(22) Filed: Mar. 7, 2014

(30) Foreign Application Priority Data
Sep. 12, 2013 (JP) 2013-189798

(51) Int. Cl. H01L 29/16

(52) U.S. Cl. CPC H01L 29/1608
USPC 257/77

(57) ABSTRACT

According one embodiment, a semiconductor device includes: a first electrode; a second electrode; a first semiconductor layer of a first conductivity type provided between the first electrode and the second electrode, the first semiconductor layer including silicon carbide; a second semiconductor layer of the first conductivity type provided between the first semiconductor layer and the second electrode, the second semiconductor layer having a lower impurity concentration than the first semiconductor layer, and the second semiconductor layer including silicon carbide; a third semiconductor layer of a second conductivity type provided between the second semiconductor layer and the second electrode, and the third semiconductor layer including silicon carbide; and a plurality of insulating layers provided between the third semiconductor layer and the second electrode.

### CROSS-REFERENCE TO RELATED APPLICATIONS

This application is based upon and claims the benefit of priority from Japanese Patent Application No. 2013-189798, filed on Sep. 12, 2013; the entire contents of which are incorporated herein by reference.

### FIELD

Embodiments described herein relate generally to a semiconductor device.

### BACKGROUND

MOS (metal-oxide-semiconductor) transistors, IGBTs (insulated gate bipolar transistors), diodes and the like are known as semiconductor devices used for power conversion devices such as inverters. The diode is used for reverse conduction and connected antiparallel to the IGBT. Thus, this diode is referred to as free wheeling diode (FWD). For the characteristics improvement of a power conversion device, it is important to improve the characteristics, such as on-resistance, of the FWD in conjunction with improving the characteristics of MOS transistors and IGBTs.

### BRIEF DESCRIPTION OF THE DRAWINGS

FIG. 1A is a schematic sectional view of a semiconductor device according to an embodiment, and FIG. 1B is a schematic plan view of the semiconductor device according to the embodiment;

FIG. 2 is a schematic sectional view of a semiconductor device according to reference example 1;

FIG. 3 is a schematic sectional view of a semiconductor device according to reference example 2;

FIG. 4 is a schematic sectional view showing the function and effect of the semiconductor device according to the embodiment; and

FIG. 5 is a schematic sectional view of a variation of the semiconductor device according to the embodiment.

### DETAILED DESCRIPTION

In general, according one embodiment, a semiconductor device includes: a first electrode; a second electrode; a first semiconductor layer of a first conductivity type provided between the first electrode and the second electrode, the first semiconductor layer including silicon carbide; a second semiconductor layer of the first conductivity type provided between the first semiconductor layer and the second electrode, the second semiconductor layer having a lower impurity concentration than the first semiconductor layer, and the second semiconductor layer including silicon carbide; a third semiconductor layer of a second conductivity type provided between the second semiconductor layer and the second electrode, and the third semiconductor layer including silicon carbide; and a plurality of insulating layers provided between the third semiconductor layer and the second electrode.

Embodiments will now be described with reference to the drawings. In the following description, like members are labeled with like reference numerals. The description of the members once described is omitted appropriately.

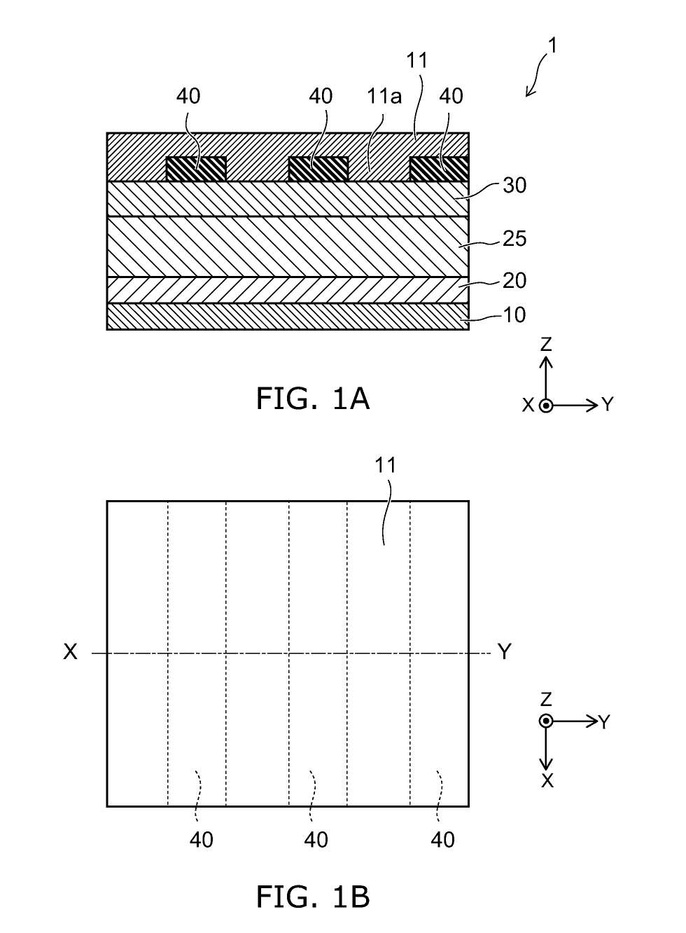

FIG. 1A is a schematic sectional view of a semiconductor device according to an embodiment. FIG. 1B is a schematic plan view of the semiconductor device according to the embodiment.

FIG. 1A shows a cross section at the position of line X-Y in FIG. 1B.

The semiconductor device 1 is a diode of the P-i-N structure used for a high-voltage rectification apparatus. The semiconductor device 1 includes a cathode electrode 10 (first electrode), an anode electrode 11 (second electrode), an n⁺-type semiconductor layer 20 (first semiconductor layer), an n⁻-type semiconductor layer 25 (second semiconductor layer), a p⁺-type semiconductor layer 30 (third semiconductor layer), and a plurality of insulating layers 40.

Here, the n⁺-type and n⁻-type (first conductivity type) impurity element can be e.g. phosphorus (P), arsenic (As), nitrogen (N) or the like. The p⁺-type (second conductivity type) impurity element can be e.g. boron (B), gallium (Ga), aluminum (Al) or the like.

In the semiconductor device 1, the semiconductor layers 20, 25, and 30 are provided between the cathode electrode 10 and the anode electrode 11. For instance, the high-concentration semiconductor layer 20 is provided between the cathode electrode 10 and the low-concentration semiconductor layer 25. The semiconductor layer 25 is provided between the semiconductor layer 20 and the high-concentration semiconductor layer 30. The impurity concentration of the semiconductor layer 25 is lower than the impurity concentration of the semiconductor layers 20 and 30. The semiconductor layer 30 is provided between the semiconductor layer 25 and the anode electrode 11. The semiconductor layer 30 is formed by ion implantation of a p-type impurity element into the semiconductor layer 25.

The plurality of insulating layers 40 are provided between the semiconductor layer 30 and the anode electrode 11. The plurality of insulating layers 40 are arranged with a prescribed spacing in the Y-direction. That is, the anode electrode 11 in contact with the semiconductor layer 30 is separated into small segments by the insulating layers 40. Each of the plurality of insulating layers 40 extends in the X-direction. The pitch in the Y-direction of the plurality of insulating layers 40 is e.g. 2 μm.

An extending portion 11a extending from the anode electrode 11 is provided between the plurality of insulating layers 40. The extending portion 11a is in contact with the semiconductor layer 30. The extending portion 11a is a portion of the anode electrode 11.

In the semiconductor device 1, the thickness of the semiconductor layer 30 is equal to or thinner than the diffusion length of electrons flowing in the semiconductor layer 30. For instance, the thickness of the semiconductor layer 30 is 1 μm or less, such as 0.5 μm. At on-time, the anode electrode 11 is applied with a higher voltage than the cathode electrode 10.

The material of the semiconductor layers 20 and 25 and the material of the semiconductor layer 30 include silicon carbide (SiC), silicon (Si) or the like. In the embodiment, the function of the semiconductor device 1 is described in the case where the material of the semiconductor layers 20 and 25 and the material of the semiconductor layer 30 are silicon carbide (SiC).

The impurity concentration of the semiconductor layer 20 is e.g. 1×10¹⁸-1×10¹⁹ atoms/cm³. The impurity concentration of the semiconductor layer 25 is e.g. 1×10¹⁵ atoms/cm³. The impurity concentration of the semiconductor layer 30 is e.g. 1×10¹⁸-1×10¹⁹ atoms/cm³.

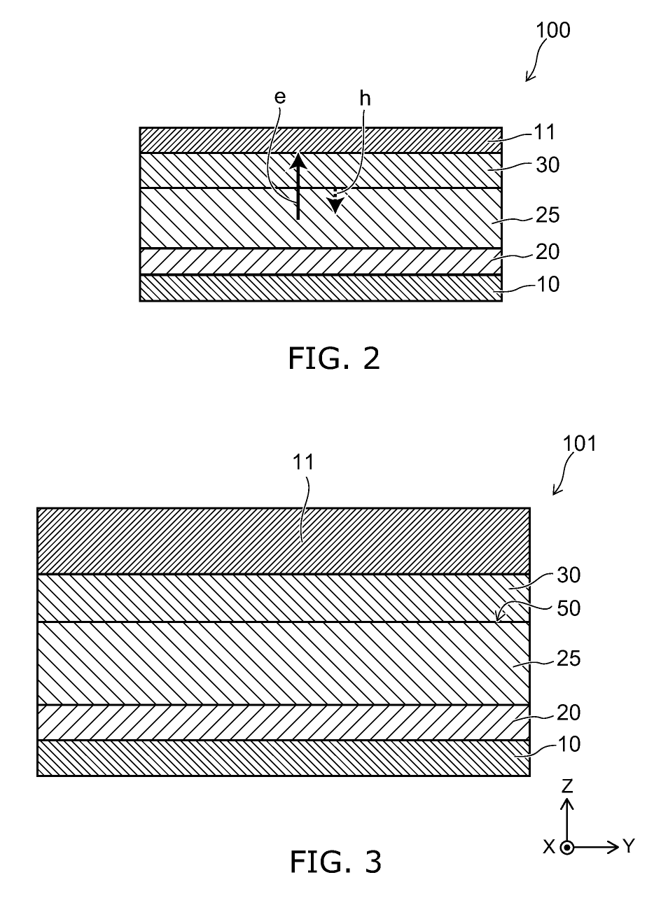

FIG. 2 is a schematic sectional view of a semiconductor device according to reference example 1.

In the semiconductor device 100 according to the reference example, the insulating layers 40 are removed from the semiconductor device 1. That is, in the semiconductor device 100 according to the reference example, the semiconductor layer 20 is provided between the cathode electrode 10 and the semiconductor layer 25. The semiconductor layer 25 is provided between the semiconductor layer 20 and the semiconductor layer 30. The semiconductor layer 30 is provided between the semiconductor layer 25 and the anode electrode 11. Furthermore, the semiconductor device 100 includes no insulating layers 40.

In the case where the material of the semiconductor layers 20, 25, and 30 is silicon carbide, the position of the p-n junction 50 cannot be made deeper than in the case where the semiconductor material is silicon. This is because the diffusion coefficient of the impurity element in silicon carbide is smaller than the diffusion coefficient of the impurity element in silicon. Thus, in the case where silicon carbide is selected as the semiconductor material, the p-n junction 50 is formed at a shallow position in the surface layer of the semiconductor layer 25.

Accordingly, the thickness of the p⁺-type semiconductor layer 30 is made thinner (e.g., 1 μm or less). This inhibits the increase of the injection efficiency of holes in the on-state of the semiconductor device 100 (the efficiency of injecting holes (h) from the semiconductor layer 30 into the semiconductor layer 25). That is, in the semiconductor device 100, the current flowing between the cathode and the anode is primarily based on electrons (e). Furthermore, because the injection efficiency of holes (h) is not increased, conduction modulation does not easily occur in the semiconductor layer 25. This makes it difficult to reduce the on-resistance of the semiconductor device 100.

Another function of the P-i-N diode is described below.

FIG. 3 is a schematic sectional view of a semiconductor device according to reference example 2.

FIG. 3 shows a typical diode 101 (semiconductor device 101) of the P-i-N structure.

The diode 101 includes a high-concentration n-type semiconductor layer 20, a low-concentration n-type semiconductor layer (n-type semiconductor i-layer 25), and a high-concentration p-type semiconductor layer 30. When a reverse bias is applied to this diode 101, the low-concentration semiconductor layer 25 is depleted. Here, reverse bias means voltage application in which the cathode electrode 10 is higher in potential than the anode electrode 11. For instance, in the diode 101, 4H-type SiC is used for the semiconductor layer. The breakdown electric field intensity is e.g. 2 MV/cm. Then, when the thickness of the semiconductor layer 25 is 50 μm, the diode 101 of an ideal parallel plate structure has a withstand capability up to a reverse bias of 10 kV.

In the forward bias state, holes are injected from the high-concentration semiconductor layer 30 into the semiconductor layer 25, and electrons are injected from the high-concentration semiconductor layer 20 into the semiconductor layer 25. This reduces the resistance of the semiconductor layer 25. Thus, the forward potential drop can be decreased. Here, forward bias means voltage application in which the anode electrode 11 is higher in potential than the cathode electrode 10.

Here, consider the state in which the doping concentration of the semiconductor layer 25 is very low. Then, in the forward bias state, it can be regarded that Nn (electron concentration)=Np (hole concentration). Reducing the resistance of the semiconductor layer 25 in the forward bias state requires increasing the carrier concentration Np (Nn).

On one hand, at the interface between the semiconductor layer 30 and the semiconductor layer 25, in order to inject holes from the semiconductor layer 30 into the semiconductor layer 25, the proportion of the hole current in the total current needs to be sufficiently large. Thus, the component of the electron current needs to be decreased.

On the other hand, excessive injection of holes into the semiconductor layer 25 under forward bias may cause degradation of recovery characteristics at switching time. For instance, the ejection time of carriers may be increased, or the current waveform may be made steeper. Thus, the diode of the P-i-N structure needs a means for adjusting the efficiency of injecting holes from the high-concentration P-type anode layer 30 (semiconductor layer 30) into the low-concentration semiconductor layer 25.

On the semiconductor layer 30 side of the junction between the semiconductor layer 30 and the semiconductor layer 25, the doping concentration of acceptors is sufficiently higher than the electron concentration. Thus, it is considered that the low injection level condition is satisfied. Accordingly, the concentration distribution of electrons injected into the sufficiently thick semiconductor layer 30 is proportional to exp(−z/Ln) based on the diffusion length Ln. Here, the absolute value of −z is the distance from the junction toward the anode side. Thus, the electron current density is expressed as Jn=qDₙn₀/Ln, where n₀ is the electron concentration on the semiconductor layer 30 side of the p-n junction 50 between the semiconductor layer 30 and the semiconductor layer 25 and Dₙ is the diffusion coefficient of minority carriers in the semiconductor layer 30. This turns to Jn=qDₙn₀/Wp in the structure in which the thickness Wp of the semiconductor layer 30 is thinner than the diffusion length of electrons. In this structure, the electron concentration becomes zero at z=Wp as in an ohmic electrode.

Thus, for instance, the injection efficiency of holes can be adjusted by adjusting the thickness of the semiconductor layer 30. For silicon semiconductor, in anode formation, the thickness of the semiconductor layer 30 can be adjusted in a wide range by adjusting the diffusion time or diffusion temperature of p-type impurity such as boron (B) to change the diffusion depth. That is, the injection efficiency of holes can be easily adjusted in a diode based on silicon semiconductor.

However, in silicon carbide (SiC), the diffusion constant of impurity is extremely low. Thus, the depth of the p-n junction cannot be adjusted in the diffusion process. Currently, the means for impurity doping in SiC is substantially limited to ion implantation or epitaxial growth. In epitaxial growth, the p-n junction depth can be controlled by growth time. However, this process is very expensive.

On the other hand, in ion implantation, the junction depth is determined by the implantation energy of impurity ions. In the ion implantation apparatus having an acceleration voltage of several hundred kV currently in widespread use, the implantation depth into SiC of aluminum ions serving as acceptors is 1 μm or less (e.g., in the range of several hundred nm). Thus, the P-i-N diode of SiC with the anode formed by ion implantation has a very shallow junction depth. This results in a large electron current density traversing the p-n junction 50 between the semiconductor layer 30 and the semiconductor layer 25. Thus, the hole injection into the semiconductor layer 25 is decreased. This causes the problem of failing to reduce the on-resistance.

In contrast, the function and effect of the semiconductor device 1 of the embodiment are described below. According to the embodiment, the injection efficiency of holes can be adjusted in a wide range in the shallow p⁺-type anode layer 30 (semiconductor layer 30) formed by ion implantation in SiC.

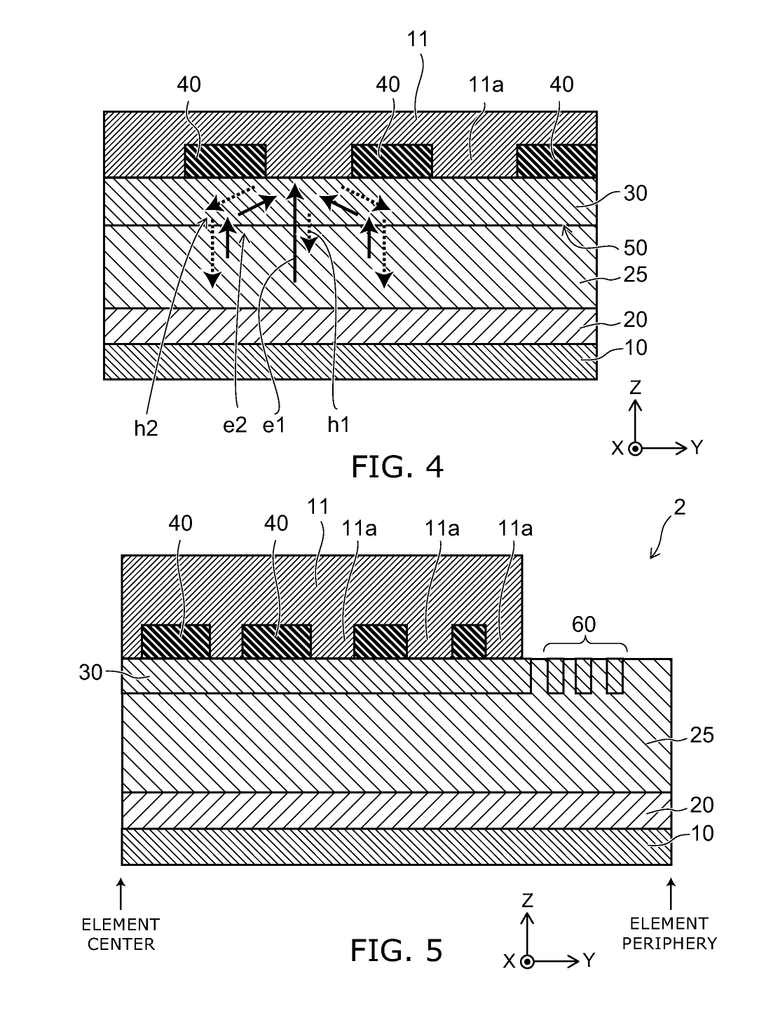

FIG. 4 is a schematic sectional view showing the function and effect of the semiconductor device according to the embodiment.

In the semiconductor device 1, carriers flowing between the cathode and the anode can be classified into carriers (electrons (e1), holes (h1)) passing in the semiconductor layer 30 directly below the extending portion 11a and carriers (electrons (e2), holes (h2)) passing in the semiconductor layer 30 directly below the insulating layer 40.

The function of the carriers (electrons (e1), holes (h1)) passing in the semiconductor layer 30 directly below the extending portion 11a is the same as the function of the carriers (electrons (e), holes (h)) in the semiconductor device 100 according to reference example 1. Here, the thickness of the semiconductor layer 30 is 1 μm or less.

However, with regard to electrons (e2) injected from the cathode side and having reached the semiconductor layer 30 directly below the insulating layer 40, the surface recombination rate of minority carriers at the interface between the insulating layer 40 and the semiconductor layer 30 is far smaller than the surface recombination rate of minority carriers at the interface between the extending portion 11a and the semiconductor layer 30. Thus, the gradient of the electron density in the Z-direction is decreased below the insulating layer 40. Accordingly, the electron current traversing the p-n junction 50 between the semiconductor layer 30 and the semiconductor layer 25 is decreased.

Thus, the efficiency of injecting holes (h2) into the semiconductor layer 25 is increased directly below the insulating layer 40.

Here, a plurality of insulating layers 40 are provided between the anode electrode 11 and the semiconductor layer 30. Thus, it may be considered that the plurality of insulating layers 40 serve as a resistance layer to increase the on-resistance between the anode and the cathode. However, the injection of holes (h2) into the semiconductor layer 25 causes conduction modulation in the portion of the semiconductor layer 25 subjected to the injection. Thus, the portion of the semiconductor layer 25 subjected to the injection of holes (h2) constitutes a low-resistance layer. This suppresses the increase of on-resistance.

Furthermore, the semiconductor of the semiconductor device 1 includes SiC. Thus, the semiconductor device 1 has a higher breakdown voltage than the diode including Si.

Thus, the injection efficiency of holes can be adjusted by discontinuously placing the extending portions 11a on the thin semiconductor layer 30. The spacing of this discontinuous placement can be easily changed and adjusted in the semiconductor element. That is, the characteristics of the semiconductor element can be easily adjusted in two dimensions in the X-Y plane. The example thereof is described below.

FIG. 5 is a schematic sectional view of a variation of the semiconductor device according to the embodiment.

In the semiconductor device 2 shown in FIG. 5, the discontinuous placement of extending portions 11a is performed in the element central portion of the diode to increase the injection efficiency of holes for resistance reduction. Furthermore, in the semiconductor device 2, the width of the plurality of insulating layers 40 is changed in the direction (e.g., X-direction or Y-direction) crossing the Z-direction from the cathode electrode 10 side to the anode electrode 11 side.

For instance, in FIG. 5, as an example, the spacing of discontinuous placement is adjusted so that the extending portions 11a are gradually made close to what is called “blanketing” the semiconductor layer 30 from the element central portion toward the element peripheral portion of the diode in the Y-direction. Thus, the injection efficiency of holes is gradually decreased. Here, reference numeral 60 represents the junction termination structure region.

In this structure, the effect of the semiconductor device 1 is maintained. Furthermore, at reverse recovery time, this structure suppresses the phenomenon in which holes injected into the high-resistance semiconductor layer 25 concentrate around the diode to cause avalanche breakdown leading to destruction.

Here, when the thickness of the semiconductor layer 30 being the P-type anode layer is comparable to or less than the diffusion length of electrons, the injection efficiency of minority carriers from the semiconductor layer 30 into the low-concentration semiconductor layer 25 can be decreased by recombination of minority carriers at the interface with the anode electrode 11. That is, the object of the embodiment, i.e., the adjustment of the efficiency of injecting holes into the semiconductor layer 25, can be achieved.

On the other hand, in order to develop the electric field intensity withstand characteristics of SiC under reverse bias, the semiconductor layer 30 needs to be designed so that the semiconductor layer 30 is not depleted even if the electric field intensity near the junction 50 between the semiconductor layer 30 and the semiconductor layer 25 reaches the breakdown electric field intensity of SiC. The breakdown electric field intensity is e.g. approximately 3 MV/cm. Thus, the surface density of acceptors ionized in the semiconductor layer 30 under reverse bias is approximately 1×10¹³/cm².

Accordingly, assuming that a typical doping concentration of the semiconductor layer 30 is 3×10¹⁸ atoms/cm³, the thickness of the semiconductor layer 30 depleted under reverse bias is 0.3 μm. The thickness of the semiconductor layer 30 is set in the range sufficiently larger than this thickness of depletion and in the range thinner than the diffusion length. Typically, it is preferable to set the thickness to 1 μm or less.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode;
a first semiconductor layer of a first conductivity type provided between the first electrode and the second electrode, the first semiconductor layer including silicon carbide;
a second semiconductor layer of the first conductivity type provided between the first semiconductor layer and the second electrode, the second semiconductor layer having a lower impurity concentration than the first semiconductor layer, and the second semiconductor layer including silicon carbide;
a third semiconductor layer of a second conductivity type provided between the second semiconductor layer and the second electrode, and the third semiconductor layer including silicon carbide; and
a plurality of insulating layers provided between the third semiconductor layer and the second electrode.

2. The device according to claim 1, wherein thickness of the third semiconductor layer is equal to or thinner than diffusion length of electrons flowing in the third semiconductor layer.

3. The device according to claim 1, wherein thickness of the third semiconductor layer is 1 μm or less.

4. The device according to claim 2, wherein thickness of the third semiconductor layer is 1 μm or less.

5. The device according to claim 1, wherein the second electrode extends between the plurality of insulating layers, and the extending second electrode is in contact with the third semiconductor layer.

6. The device according to claim 2, wherein the second electrode extends between the plurality of insulating layers, and the extending second electrode is in contact with the third semiconductor layer.

7. The device according to claim 3, wherein the second electrode extends between the plurality of insulating layers, and the extending second electrode is in contact with the third semiconductor layer.

8. The device according to claim 1, wherein width of the plurality of insulating layers changes in a direction crossing a direction from the first electrode side to the second electrode side.

9. The device according to claim 2, wherein width of the plurality of insulating layers changes in a direction crossing a direction from the first electrode side to the second electrode side.

10. The device according to claim 3, wherein width of the plurality of insulating layers changes in a direction crossing a direction from the first electrode side to the second electrode side.

11. The device according to claim 5, wherein width of the plurality of insulating layers changes in a direction crossing a direction from the first electrode side to the second electrode side.

12. The device according to claim 11, wherein the width of the plurality of insulating layers is narrowed from an element central portion toward an element peripheral portion in the direction.

13. The device according to claim 1, wherein impurity concentration of the third semiconductor layer is e.g. 1×10¹⁸-1×10¹⁹ atoms/cm³.
